(19) United States
(12) Patent Application Publication
(10) Pub. No.: US 2006/0115927 A1
(43) Pub. Date: Jun. 1, 2006

(54) Attachment of flip chips to substrates

(75) Inventors: Swain Hong Alfred Yeo, Singapore (SG); Ai Min Tan, Singapore (SG)

Correspondence Address: MAGINOT, MOOR & BECK, 111 MONUMENT CIRCLE, SUITE 3000, BANK ONE CENTER/TOWER, INDIANAPOLIS, IN, 46204, US

(73) Assignee: Infineon Technologies AG, Munchen (DE)

(21) Appl. No.: 10/536,652

(22) PCT Filed: Nov. 29, 2002
(86) PCT No.: PCT/SG02/00282

§ 371 Date: May 27, 2005

(51) Int. Cl. H01L 21/50

(52) U.S. Cl. 438/107

(57) ABSTRACT

An anisotropic conductive layer is formed between a substrate and a flip chip having multiple contacts. Insulating layers are formed on the lateral surfaces of the electrical contacts. When the flip chip is attached to a substrate, the insulating layers reduce the chance of an electrical path being formed in the lateral direction between the contacts.

### FIELD OF THE INVENTION

The present invention relates to methods for attachment of flip-chips to substrates, and to flip-chips attached to substrates using the method. The term “substrate” is used in this document in a general sense to include any body onto which a flip-chip is secured, for example a printed circuit board.

### BACKGROUND OF INVENTION

“Flip-chips” are integrated circuits formed with electrical contacts on one surface. The flip-chip is electrically connected to a substrate by positioning it with this surface facing a surface of the substrate. The substrate has electrical contacts at locations on that surface corresponding to the locations of the electrical contacts on the flip-chip.

The known connection scheme is shown in FIG. 1. The contacts 1 on the flip chip 3 are conventionally Au (gold) bumps in register with electrical contacts 11 on the substrate 13. The flip-chip 3 is fixed to the substrate by a paste or film layer 21. A paste layer is generally dispensed whereas a film layer is laminated onto the substrate 13. One possibility would be to form the paste or film layer 21 entirely of an insulating material, so that the layer is a non-conductive paste (NCP) or non-conductive film (NCF). However, this causes a risk of that an insulating layer is formed between certain of the bumps 1 and the contacts 11. To prevent this risk, the paste or film 21 may include conducting particles 23. The idea is that some of the conducting particles 23 are trapped between the bumps 1 and the contacts 11, and so form reliable conducting paths in the vertical direction, without such paths existing in the horizontal direction. Such horizontal paths would be disadvantageous, because they would cause lateral shorting between adjacent bumps 1 or contacts 11. For this reason, the paste including the conductive particles is referred to as an ACP (anisotropic conductive paste) or ACF (anisotropic conductive film).

However, with the continuous shrinking of the dimensions of the electronic packaging components, the sizes of the bumps 3, of the contacts 5, and of the spaces between them in the plane of the surfaces, must be reduced. As this happens, there is an increasing risk that a configuration of the conductive particles 23 is produced which results in electrical shorting in the horizontal direction. This risk increases as the pitch (i.e. the lateral spacing of the bumps and contacts) becomes smaller, yet it would be highly expensive to reduce the size of the conductive particles further.

### SUMMARY OF THE INVENTION

The present invention aims to provide a new and useful methods for attaching a flip-chip to a substrate and combinations of a flip-chip and substrate formed by the method.

In general terms, the invention proposes that insulating layers are formed on the lateral surfaces of the electrical contacts on the flip-chip and/or on the substrate. This has the advantage that, when the flip-chips are attached to the substrate, the chance of an electrical path being formed in the lateral direction between the contacts is very much reduced.

Preferably, the insulating layer on the lateral sides of the flip-chip electrical contacts is produced by forming an insulating film over the surface of the flip-chip having the electrical contacts, and then removing the portions of the film overlying the electrical contacts by a polishing method.

Preferably, the insulating layer on the substrate is produced by coating a photo-sensitive film onto the substrate, and irradiating selected portions of the surface (e.g. with UV radiation) to modify the material properties of the layer, such that the material overlying the contact portions can be removed selectively.

Note that it is not presently preferred to use such an irradiation technique to form the lateral films on the contacts of the flip-chip, since the flip chip may be damaged by the irradiation. Conversely, the polishing technique is not presently preferred for forming the lateral films on the contacts of the substrate, since the irradiation technique is a more mature technology, and for example does not require the electrical contacts on substrate to be formed with such a uniform height.

### BRIEF DESCRIPTION OF THE FIGURES

Preferred features of the invention will now be described, for the sake of illustration only, with reference to the following figures in which:

FIG. 1 shows the attachment of a flip-chip to a substrate according to a known method;

FIG. 2, which consists of FIGS. 2(a) to 2(c), shows the formation of lateral layers on the electrical contacts of a flip-chip in a method which is an embodiment of the invention;

FIG. 3, which consists of FIGS. 3(a) to 3(c), shows the formation of lateral layers on the electrical contacts of a substrate in the embodiment of FIG. 2; and

FIG. 4, shows the steps of attachment of the flip-chip and circuit-board formed as shown in FIGS. 2 and 3.

### DETAILED DESCRIPTION OF THE EMBODIMENTS

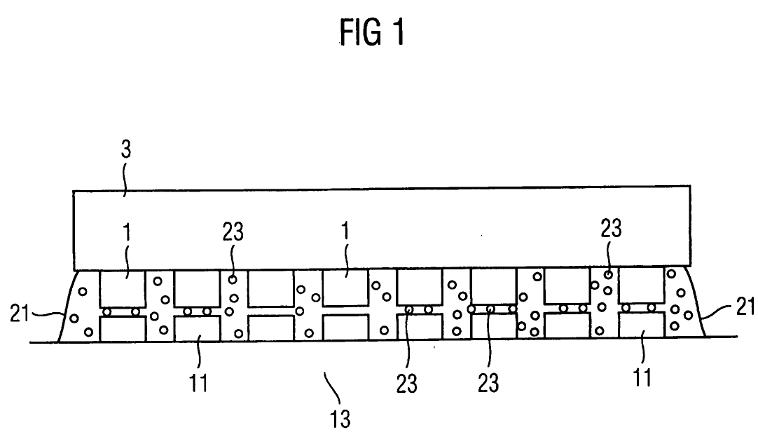

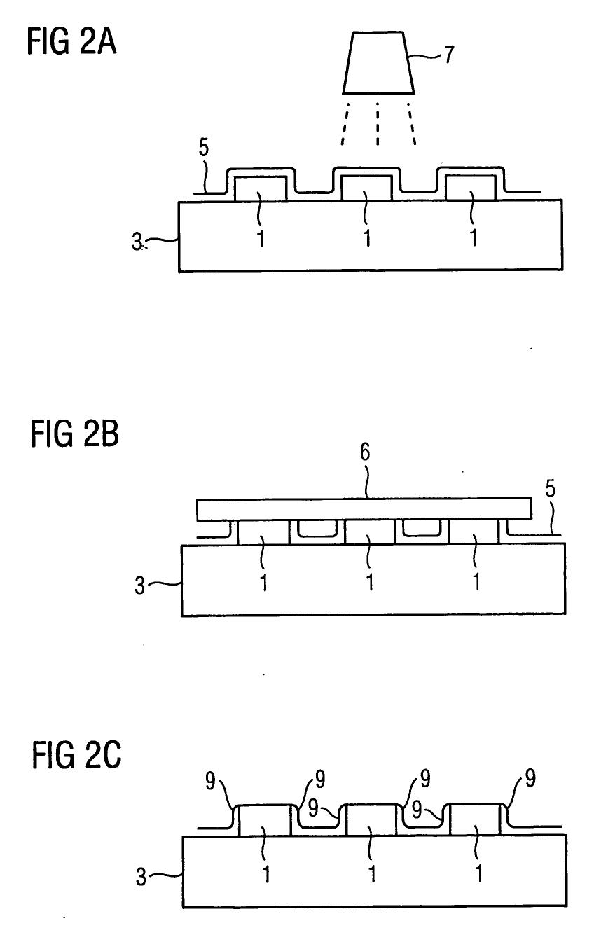

The embodiment is described with reference to FIGS. 2 to 4, which use equal references numerals to those used in FIG. 1 to label equivalent items. None of these figures is drawn to scale. Referring firstly to FIG. 2, a method is shown of forming lateral layers on the electrical contacts 1 of a flip-chip 3 in the embodiment of the invention.

In a first step, as shown in FIG. 2(a), an insulating organic polymer layer 5 is formed over the surface of the flip-chip 3 carrying the electrical contacts 1 (Au bumps). The layer 5 is typically 5 to 10 micrometers thick. After it is formed, it is cured by irradiation with a lamp 7.

As shown in FIG. 2(b), the top portions of the layer 5 (i.e. the portions which overlie the electrical contacts 1) are then removed using a chemical-mechanical polishing (CMP) or “backlapping” tool 6, to give the result shown in FIG. 2(c), in which the electrical contacts 1 having insulating layers 9 on their lateral surfaces.

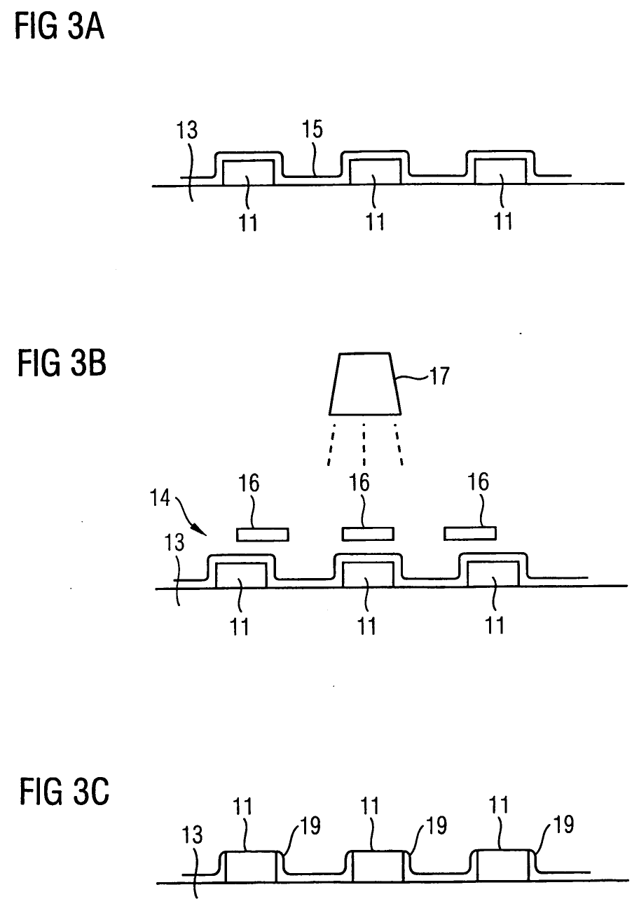

Turning now to FIG. 3, a method is shown of forming lateral layers on the electrical contacts 11 of a substrate 13 in a method according to the invention.

In a first step, shown in FIG. 3(a), a layer 15 of a photosensitive insulating material is coated over the surface of the substrate 13 carrying the electrical contacts 11.

In the next step, shown in FIG. 3(b), a mask 14 is positioned over the substrate 13 with masking portions 16 in register with the electrical contacts 11. The layer 15 is irradiated with a UV lamp 17 through the mask 14, so as to crosslink and harden the material which is not protected by the masking portions 16. The masking portions 16 mask the portions of the layer 15 on top of the electrical contacts 11, so these portions of the layer are not exposed to the UV light and will not crosslink. These portions of the layer 15 can now be removed by etching, to leave the structure shown in FIG. 3(c), including electrically insulating layers 19 on the lateral surfaces of the electrical contacts 11.

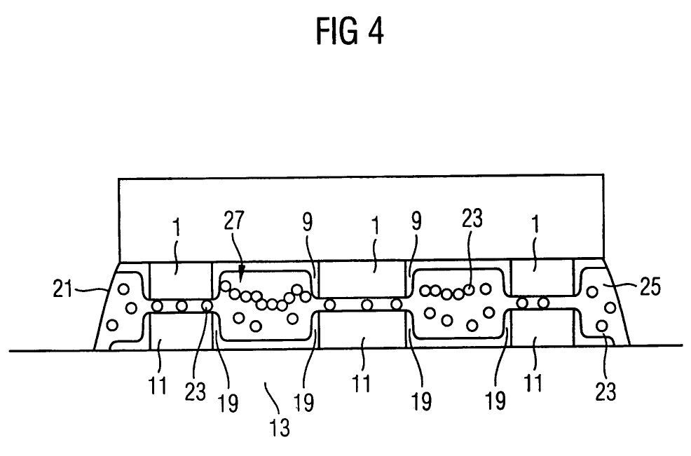

Turning now to FIG. 4, the flip-chip 3 produced as shown in FIG. 2 is connected to the substrate produced in FIG. 3, by a matrix 21 (ACF/ACP layer) containing electrically conductive particles 23 within an insulating material 25. The conductive particles 23 sandwiched between the electrical contacts 1, 11 provide conducting paths between the corresponding contacts in the vertical direction. Even if there are horizontal conducting paths 27 formed by the conductive particles 23, there is little or no risk of electrical shorting between horizontally (laterally) spaced apart electrical contacts 1, 11 due to the insulator layers 9, 19.

Many variations of the embodiment are possible within the scope of the invention as will be clear to a skilled reader. For example, in one variation the method of forming lateral films explained in FIG. 3 with reference to forming lateral insulating layers 19 on the contacts 11 of the substrate 13 could be used to produce the lateral insulating layers on the electrical contacts 1 of the flip-chip 3. However, it would be less straightforward to adapt the technique for forming lateral insulating layers shown in FIG. 2 to the formation of lateral insulating layers on the contacts 11 of the substrate 13.

1-4. (canceled)

5. A method of attaching a flip-chip to a substrate, the flip-chip including a first plurality of electrical contacts with lateral sides and the substrate including a second plurality of electrical contacts with lateral sides, the method comprising:
a. forming an insulating layer of an insulating material on the lateral sides of the first plurality of electrical contacts and on the lateral sides of the second plurality of electrical contacts; and
b. joining the flip-chip to the substrate using a matrix of insulating material including conductive particles.

6. The method of claim 5 wherein the insulating layer on the lateral sides of the first plurality of electrical contacts is formed by coating a layer of insulating material onto a surface of the flip-chip which includes the first plurality of electrical contacts, curing the layer, and removing portions of the layer overlying the first plurality of electrical contacts by polishing.

7. The method of claim 6 wherein the first plurality of electrical contacts are polished by chemical mechanical polishing.

8. The method of claim 6 wherein the first plurality of electrical contacts are polished using a backlapping tool.

9. The method of claim 5 wherein the insulating layer on the lateral sides of the second plurality of electrical contacts is formed by coating a photosensitive layer of insulating material onto a surface of the substrate which includes the second plurality of electrical contacts, exposing portions of the photosensitive layer which do not overlie the electrical contacts to electromagnetic radiation in order to cure the portions of the photosensitive layer which do not overlie the electrical contacts, and then removing uncured portions of the photosensitive layer to expose the second plurality of electrical contacts.

10. The method of claim 5 wherein joining the flip-chip to the substrate using a matrix of insulating material including conductive particles comprises joining the flip-chip to the substrate using an anisotropic conductive paste.

11. The method of claim 5 wherein joining the flip-chip to the substrate using a matrix of insulating material including conductive particles comprises joining the flip-chip to the substrate using an anisotropic conductive film.

12. A flip-chip assembly comprising:
a. a flip chip having a first surface including a first plurality of electrical contacts, the first plurality of electrical contacts including lateral sides;
b. a first electrically insulating film formed on the lateral sides of the first plurality of electrical contacts;
c. a substrate having a second surface including a second plurality of electrical contacts, the second plurality of electrical contacts including lateral sides, and the second plurality of electrical contacts facing the first plurality of electrical contacts;
d. a second electrically insulating film formed on the lateral sides of the second plurality of electrical contacts; and
e. a matrix of insulating material including electrically conductive particles between the flip chip and the substrate.

13. The assembly of claim 12 wherein the matrix of insulating material including electrically conductive particles comprises an anisotropic conductive paste.

14. The assembly of claim 12 wherein the matrix of insulating material including electrically conductive particles comprises an anisotropic conductive film.

15. The assembly of claim 12 wherein the substrate is a printed circuit board.

16. The assembly of claim 12 wherein the first plurality of electrical contacts comprise gold bumps.

17. A method of attaching a flip-chip to a substrate, the flip-chip including a first plurality of electrical contacts with lateral sides and the substrate including a second plurality of electrical contacts with lateral sides, the method comprising:
a. forming an insulating layer on the lateral sides of the first plurality of electrical contacts by coating a layer of insulating material onto a surface of the flip-chip which includes the first plurality of electrical contacts, curing the layer of insulating material, and removing portions of the layer of insulating material overlying the first plurality of electrical contacts by chemical mechanical polishing;
b. forming an insulating layer of an insulating material on the lateral sides of the second plurality of electrical contacts by coating a layer of photosensitive insulating material onto a surface of the substrate which includes the second plurality of electrical contacts, exposing portions of the layer of photosensitive insulating material which do not overlie the electrical contacts to electromagnetic radiation in order to cure the portions of the layer of photosensitive insulating material which do not overlie the electrical contacts, and then removing uncured portions of the layer of photosensitive insulating material to expose the second plurality of electrical contacts; and
c. joining the flip-chip to the substrate using a matrix of insulating material including conductive particles.

18. The method of claim 17 wherein joining the flip-chip to the substrate using a matrix of insulating material including conductive particles comprises joining the flip-chip to the substrate using an anisotropic conductive paste.

19. The method of claim 17 wherein joining the flip-chip to the substrate using a matrix of insulating material including conductive particles comprises joining the flip-chip to the substrate using an anisotropic conductive film.
